(19) United States
(12) Patent Application Publication
(10) Pub. No.: US 2024/0409750 A1
(43) Pub. Date: Dec. 12, 2024

(54) HIGH ENERGY RAY-CURABLE COMPOSITION AND USE OF SAME

(71) Applicant: DOW TORAY CO., LTD., Shinagawa-Ku, Tokyo (JP)

(72) Inventors: Takuya OGAWA, Ichihara-shi, Chiba (JP); Tomoka HOSOKAWA, Ichihara-shi, Chiba (JP)

(21) Appl. No.: 18/690,404

(22) PCT Filed: Aug. 31, 2022
(86) PCT No.: PCT/JP2022/032783

§ 371 Date: Mar. 8, 2024

(30) Foreign Application Priority Data
Sep. 10, 2021 (JP) 2021-147623

(51) Int. Cl. C09D 4/00; C08F 220/18; C08F 222/10; C09D 133/06; C09D 135/02

(52) U.S. Cl. CPC C09D 4/00; C08F 220/1811; C08F 222/102; C08F 222/103; C09D 133/062; C09D 135/02; C08F 2800/20

(57) ABSTRACT

Provided is a high energy ray-curable composition containing silicon atoms, in which the cured product has high transparency and low dielectric properties, and has low viscosity and excellent workability when applied to a substrate even when the composition is solvent free. The high energy ray-curable composition comprises: (A) 5 parts by mass to 95 parts by mass of a compound having one or more (meth)acryloxy groups and no silicon atoms in the molecule; and (B) 95 parts by mass to 5 parts by mass of a branched organopolysiloxane having one (meth)acryloxy group and no alkoxy group in a molecule, some of the oxygen atoms being substitutable with a divalent alkylene group having no more than 6 carbon atoms. The high energy ray-curable composition contains substantially no organic solvent and the viscosity of the entire composition (measured at 25° C. using an E-type viscometer) is 500 mPa's or less.

### TECHNICAL FIELD

The present invention relates to high energy ray-curable compositions curable by chemical beams (actinic rays), for example, ultraviolet light or electron beams, and in particular to high energy ray-curable compositions containing organosilicon compounds, preferably organopolysiloxanes, especially those having low viscosity and excellent application properties. Because the cured materials obtained therefrom exhibit a low dielectric constant, the curable compositions of the present invention are suitable as an insulating material for electronic and electrical devices, especially for use as a coating agent. Furthermore, the composition has excellent application properties and superior wettability to substrates, thus being useful as an injection molding material and inkjet printing material.

### BACKGROUND ART

Due to high heat resistance and excellent chemical stability, silicone resins have been used as coating agents, potting agents, insulating materials, and the like for electronic and electrical devices. Among silicone resins, high energy ray-curable silicone compositions have also been reported.

Touch panels are used in various display devices such as mobile devices, industrial equipment, car navigation systems, and the like. In order to improve detection sensitivity, electrical influence from light emitting sites such as light emitting diodes (LED) and organic light emitting devices (OLED) must be suppressed, and an insulating layer is usually placed between the light emitting part and the touchscreen.

On the other hand, thin display devices such as OLEDs have a structure in which a plurality of functional thin layers are stacked. In recent years, studies have been started in order to improve the overall reliability of display devices, especially flexible display devices, by laminating an insulating layer with high flexibility onto the touchscreen layer. In addition, the inkjet printing method has been adopted as a processing method for organic layers to improve productivity. Therefore, a material that can be processed by the inkjet printing method is required for the aforementioned insulating layer.

Patent Document 1 (European Unexamined Patent Application No. 2720085) discloses a high energy ray-curable composition comprising a monomer having a (meth)acryloxy functional group and a silane having a (meth)acryloxy functional group, and a barrier layer obtained from this composition. Patent Document 2 (International Patent Application Publication No. WO 2018-3381 A1) discloses a linear silicone having 12 or more silicon atoms with (meth)acryloxy functionality at both ends, and a high energy ray-curable inkjet ink composition comprising a monomer having (meth)acryloxy functional groups. Although the viscosity of each composition is low, the dielectric properties of the cured product are neither described nor suggested.

Patent Document 3 (Japanese Unexamined Patent Application No. 2020-70358) discloses a radiation curable organosilicon resin composition with excellent gas barrier properties, comprising a linear silicone with three or less silicon atoms of (meth)acryloxy functionality at both ends. Although the composition disclosed therein has a low molecular weight, it has a high viscosity, so that the processing method is limited and it is not suitable for application by an ink jet method.

Patent Document 4 (Japanese Unexamined Patent Application No. 2020-53313) discloses a high energy ray-curable resin composition for inkjet printable organic EL encapsulation, comprising a monomer having a (meth)acryloxy functional group and a silicone compound having a methoxy group. A large number of methoxy groups present in the composition improve adhesion to a substrate, but there is a concern that physical properties of the composition such as viscosity may change due to moisture absorption.

In addition, methoxy group and silanol groups generated by moisture absorption have anisotropy, so are not preferable in a low dielectric material.

As mentioned above, there are many known high energy ray-curable compositions containing organopolysiloxanes with (meth)acryloxy functional groups, but problems remain to be improved as high energy ray-curable compositions that are solvent-free but have excellent workability, especially low viscosity, for application to substrates by ink-jet methods, etc., and that have a cured product with a low dielectric constant.

### RELATED ART DOCUMENTS

### Patent Documents

Patent Document 1: European Unexamined Patent Application No. 2720085
Patent Document 2: International Patent Application Publication No. WO 2018/3381 A1 Pamphlet
Patent Document 3: Japanese Unexamined Patent Application No. 2020-70358
Patent Document 4: Japanese Unexamined Patent Application No. 2020-53313

### SUMMARY OF THE INVENTION

### Problem to be Solved by the Invention

The present invention seeks to provide a curable composition containing silicon atoms, especially a high energy ray-curable composition, that allows for easy adjustment of the mechanical properties of the cured product, that can be designed with a wide range of hardnesses, etc., and that produces a cured product having excellent workability when applied to a substrate even when the composition is solvent free, and having a low dielectric constant.

### Means for Solving the Problem

The present invention is a product of a discovery that a high energy ray-curable composition combining (A) 5 parts by mass to 95 parts by mass of a compound having one or more (meth)acryloxy groups and no silicon atoms in the molecule and (B) 95 parts by mass to 5 parts by mass of a branched organopolysiloxane having one (meth)acryloxy group and no alkoxy group in the molecule, some of the oxygen atoms being substitutable with a divalent alkylene group having no more than 6 carbon atoms, has low viscosity and excellent workability when applied to a substrate, even without the substantial use of an organic solvent, and the cured product thereof exhibits excellent mechanical and dielectric properties.

The present invention relates to a high energy ray-curable composition containing an organosilicon compound, in particular an ultraviolet curable organopolysiloxane composition. While this composition is cured by the formation of bonds by ultraviolet curable functional groups, the curing method is not limited to ultraviolet irradiation, and any method enabling the curing functional groups to cause a curing reaction can be used. For example, electron beam irradiation may be used to cure this composition.

The present invention is a high energy ray-curable composition comprising:
(A) 5 parts by mass to 95 parts of a compound having one or more (meth)acryloxy groups and no silicon atoms in the molecule; and
(B) 95 parts by mass to 5 parts by mass of a branched organopolysiloxane having one (meth)acryloxy group and no alkoxy group in the molecule, some of the oxygen atoms being substitutable with a divalent alkylene group having no more than 6 carbon atoms, wherein the composition contains substantially no organic solvent, and the viscosity of the entire composition measured at 25° C. using an E-type viscometer is 500 mPa-s or less. Note that unless otherwise specified herein, the viscosity of a substance is the value measured using an E-type viscometer at 25° C.

Component (A) in the curable composition may be a compound having one (meth)acryloxy group and no silicon atom or a mixture of two or more compounds having one (meth)acryloxy group and no silicon atom.

Component (A) above may be a mixture of one or more compounds having one (meth)acryloxy group and no silicon atom and one or more compounds having two or more (meth)acryloxy groups and no silicon atom.

Component (A) may be a compound having one or more acryloxy groups and no silicon atoms in the molecule.

Component (B) is preferably a branched organopolysiloxane having an organosiloxy unit represented by the following formula (1) below and having no alkoxy group, some of the oxygen atoms being substitutable with a divalent alkylene group having no more than 6 carbon atoms.

RSiO_{3/2} (1)

(In this formula, R is a group containing a (meth)acryloxy group.)

Component (B) is preferably a branched organopolysiloxane represented by formula (2) below.

RSi[O(SiZ₂X)ₙSiY₃]₃ (2)

(In this formula, R is a group containing a (meth)acryloxy group, X is a divalent alkylene group having no more than 6 carbon atoms, Y is a group selected from an unsubstituted or fluorine-substituted monovalent hydrocarbon group having no more than 10 carbon atoms, or OSiZ₃, Z is an unsubstituted or fluorine-substituted monovalent hydrocarbon group having no more than 10 carbon atoms, and n is 0 or 1.)

Preferably, the viscosity of the entire composition measured at 25° C. using an E-type viscometer is 5 to 100 mPa·s.

The viscosity of the entire composition when measured at 25° C. using an E-type viscometer is particularly preferably within a range of 5 to 30 mPa·s.

The present invention further provides an insulating coating agent containing the high energy ray-curable composition described above. The high energy ray-curable composition of the present invention is useful as an insulating coating agent.

The present invention further provides a cured product of the high energy ray-curable composition described above. Furthermore, the present invention also provides a method of using the cured product as an insulating coating layer.

The present invention further provides a display device such as a liquid crystal display, organic EL display, or organic EL flexible display that includes a layer containing a cured product of the above-described high energy ray-curable composition.

### Effect of the Invention

The high energy ray-curable composition of the present invention has the advantages of being solvent-free while having a moderate viscosity that provides good workability when applied to a substrate and excellent wettability, and the cured product thereof can be designed with a wide range of hardnesses, etc., and has a low dielectric constant. The composition also has excellent storage stability and can maintain good coating and curing properties over a long period of time because the physical properties of the composition do not readily change. Therefore, the high energy ray-curable composition of the present invention is useful as a material for forming a low dielectric constant layer, especially one for electronic devices, and as a material for an insulating layer, especially as a coating material, in any field where a material with a low dielectric constant is required.

### DESCRIPTION OF THE PREFERRED EMBODIMENTS

A configuration of the present invention will be further described in detail below. The present invention is a high energy ray-curable composition comprising as essential components:
(A) 5 parts by mass to 95 parts by mass of a compound having one or more (meth)acryloxy groups and no silicon atoms in the molecule; and
(B) 95 parts by mass to 5 parts by mass of a branched organopolysiloxane having one (meth)acryloxy group and no alkoxy group in the molecule, some of the oxygen atoms being substitutable with a divalent alkylene group having no more than 6 carbon atoms. If necessary, a component selected from a photo-radical polymerization initiator and various additives may be included. However, the curable composition of the present invention is characterized by substantially not containing organic solvent. In the present specification, “(meth)acryloxy group” refers to “a functional group selected from a methacryloxy group and an acryloxy group”. Compounds having a (meth)acryloxy groups include both methacrylate compounds and acrylate compounds.

In the present specification, the term “polysiloxane” refers to a siloxane unit (Si—O) with a degree of polymerization of two or more, in other words with an average of two or more Si—O bonds per molecule. Polysiloxanes include siloxane oligomers such as disiloxanes, trisiloxanes, tetrasiloxanes, and the like, as well as siloxane polymers with higher degrees of polymerization. Component (B) includes those having a silalkylene structure in which a portion of the siloxane structure between silicon atoms represented by Si—O—Si is substituted with an alkylene having no more than 6 carbon atoms (preferably in the range of 2 to 6).

### [Component (A)]

Component (A) may be a compound having one or more (meth)acryloxy groups and no silicon atom in the molecule. There is no restriction on the molecular structure as long as this object can be achieved, and the structure can be straight-chain, branched, cyclic, box-shaped, or any other type.

The viscosity of component (A) at 25° C. is preferably 1 to 500 mPa·s, more preferably 1 to 100 mPa·s, even more preferably 1 to 20 mPa·s.

Furthermore, the aforementioned component (A) contains 1 to 4 (meth)acryloxy groups per molecule, preferably 1 to 3 groups, and even more preferably 1 to 2 groups. In compounds with a plurality of acryloxy groups, there is no restriction on the positions of the (meth)acryloxy groups in the molecule, and the groups can be close together or far apart.

The aforementioned component (A) may be a single compound having one (meth)acryloxy group or a mixture of two or more compounds, each having one acryloxy group.

Furthermore, the aforementioned component (A) may be a mixture of one or more compounds having one (meth)acryloxy group and a compound having two or more (meth)acryloxy groups.

Component (A) may be one or more compounds with one acryloxy group, or a mixture of one or more compounds with one acryloxy group and one or more compounds with two or more acryloxy groups.

Specific examples of compounds with one (meth)acryloxy group include isoamyl acrylate, isoamyl methacrylate, octyl acrylate, octyl methacrylate, dodecyl acrylate, dodecyl methacrylate, lauryl acrylate, lauryl methacrylate, stearyl acrylate, stearyl methacrylate, diethylene glycol monoethyl ether acrylate, diethylene glycol monoethyl ether methacrylate, diethylene glycol monomethyl ether acrylate, diethylene glycol monomethyl ether methacrylate, 2-ethylhexyl acrylate, 2-ethylhexyl methacrylate, phenoxyethyl acrylate, phenoxyethyl methacrylate, diethylene glycol monophenyl ether acrylate, diethylene glycol monophenyl ether methacrylate, 4-hydroxybutyl acrylate, 4-hydroxybutyl methacrylate, 2-hydroxypropyl acrylate, 2-hydroxypropyl methacrylate, tetrahydrofurfuryl acrylate, tetrahydrofurfuryl methacrylate, isobornyl acrylate, isobornyl methacrylate, dicyclopentanyl acrylate, dicyclopentanyl methacrylate, dicyclopentenyl acrylate, dicyclopentenyl methacrylate, 3,3,5-tricyclohexyl acrylate, and 3,3,5-tricyclohexyl methacrylate. These may be used alone or in a mixture of two or more.

Compounds with one (meth)acryloxy group can be used individually, or in combinations of two or more groups, taking into consideration the viscosity of the compound, curing properties, hardness after curing, and the glass transition temperature. Among these, acrylate or methacrylate compounds with 8 or more carbon atoms in the molecule are particularly suitable from the standpoint of their low volatility, the low viscosity of the composition, and the high glass point transfer temperature of the cured product. Preferred examples that can be used include 2-ethylhexyl acrylate, 2-ethylhexyl methacrylate, isobornyl acrylate, isobornyl methacrylate, dicyclopentanyl acrylate, dicyclopentanyl methacrylate, dicyclopentenyl acrylate, and dicyclopentenyl methacrylate.

Specific examples of compounds having two or more (meth)acryloxy groups include diethylene glycol diacrylate, diethylene glycol dimethacrylate, triethylene glycol diacrylate, triethylene glycol dimethacrylate, neopentyl glycol diacrylate, neopentyl glycol dimethacrylate, polyethylene glycol diacrylate, polyethylene glycol dimethacrylate, 1,4-bis(acryloyloxy) butane, 1,4-bis(methacryloyloxy) butane, 1,6-bis(acryloyloxy)hexane, 1,6-bis(methacryloyloxy)hexane, 1,9-bis(acryloyloxy)nonane, 1,9-bis(methacryloyloxy)nonane, tricyclodecanedimethanol diacrylate, tricyclodecanedimethanol dimethacrylate, trimethylolpropane triacrylate, trimethylolpropane trimethacrylate, tris(2-acryloyloxy)ethyl isosialate, tris(2-methacryloyloxy)ethyl isosialylate, pentaerythritol tetraacrylate, and pentaerythritol tetramethacrylate.

Compounds with two or more acryloxy groups can be used individually, or in combinations of two or more groups, taking into consideration the viscosity of the compound, curing properties, compatibility with the aforementioned compounds having one (meth)acryloxy group, hardness after curing, and the glass transition temperature. Diethylene glycol diethylene diacrylate, glycol dimethacrylate, 1,6-bis(acryloyloxy)hexane, 1,6-bis(methacryloyloxy)hexane, tricyclodecane dimethanol diacrylate, tricyclodecanedimethanol dimethacrylate, trimethylolpropane triacrylate, trimethylolpropane trimethacrylate, pentaerythritol tetraacrylate, and pentaerythritol tetramethacrylate are preferably used.

Furthermore, in consideration of the aforementioned properties, these compounds having two or more (meth)acryloxy groups can be used in combination with the compounds having one acryloxy group. In this case, both can be combined in any ratio, but usually the ratio of [compounds with two or more acryloxy groups]/[compounds with one (meth)acryloxy group] ranges from 1/99 to 80/50 (mass ratio). If the ratio of compounds having two or more (meth)acryloxy groups is too high, the cured material may become hard and brittle.

### [Component (B)]

The component (B) is a branched organopolysiloxane having one silicon-bonded (meth)acryloxy group-containing organic group and no alkoxy group in the molecule, some of the oxygen atoms being substitutable with a divalent alkylene group having no more than 6 carbon atoms. By having a branched structure, the viscosity is lower than that of a linear polysiloxane having the same degree of polymerization molecular weight, and compatibility with component (A) is also improved. Component (B) does not contain more than one (meth)acryloxy group.

Component (B) can be a branched organopolysiloxane having an organosiloxy unit represented by formula (1) below.

RSiO_{3/2} (1)

(In this formula, R is an organic group comprising a (meth)acryloxy group.)

The group containing a (meth)acryloxy group represented by R in the formula (1) is preferably a group represented by the formula (3) below.

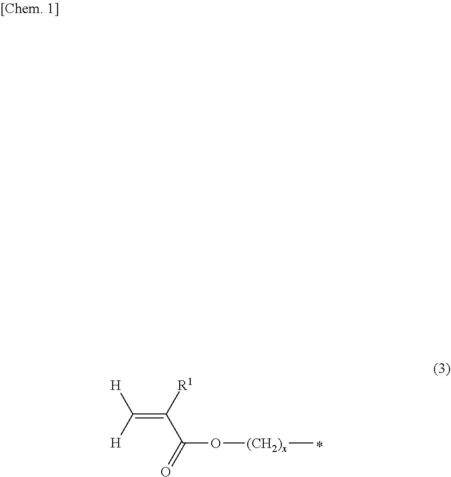

(In this formula, R¹ is a hydrogen atom or a methyl group, x is a number between 2 and 10, and the bond to a silicon atom constituting the branched polysiloxane is represented by an asterisk.)

The branched organopolysiloxane (B) has one (meth)acryloxy group-containing organic group bonded to a silicon atom in the molecule. When the compound has two or more (meth)acryloxy group-containing organic groups, the compound functions as a monomer for forming an intermolecular crosslinking structure, and thus the object of the present invention may not be achieved.

Component (B) is preferably a branched organopolysiloxane represented by the following structural formula (2).

RSi[O(SiZ₂X)ₙSiY₃]₃ (2)

In the formula, R is a group containing the (meth)acryloxy group described above. X represents a divalent alkylene group having no more than 6 carbon atoms. Examples include a methylene group, an ethylene group, a propylene group, a butylene group, a hexylene group, and a CH(CH₃) group. However, an ethylene group is preferred. Y is an unsubstituted or fluorine-substituted monovalent hydrocarbon group having 10 or less carbon atoms or a group selected from OSiZ₃, and Z is an unsubstituted or fluorine-substituted monovalent hydrocarbon group having 10 or less carbon atoms. Y being a unsubstituted or fluorine substituted monovalent hydrocarbon group with 10 or less carbon atoms is preferably a group selected from alkyl, cycloalkyl, arylalkyl, and aryl groups that are unsubstituted or fluorine substituted. Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable.

Examples of the cycloalkyl groups above include cyclopentyl, cyclohexyl, and the like. Examples of the arylalkyl groups above include benzyl, phenylethyl groups, and the like. The aryl groups described above include phenyl, tolyl, and naphthyl groups. Examples of fluorine-substituted monovalent hydrocarbon groups include 3,3,3-trifluoropropyl and 3,3,4,4,5,5,6,6,6-nonafluorohexyl groups. Among these groups, a methyl group is preferably used. Z is an unsubstituted or fluorine-substituted monovalent hydrocarbon group having 10 or less carbon atoms. Examples include those mentioned above, and similarly, a methyl group can be used as a preferable group.

Also, n is 0 or 1. When this number is 0, component B becomes a branched organopolysiloxane, and when this number is 1, the component (B) becomes a branched organopolysiloxane having a silalkylene partial structure represented by Si(Z)₂—X—SiY₃ in which some of the oxygen atoms are substituted with a divalent alkylene group (X).

Preferred examples of component (B) include acryloxypropyltristrimethylsiloxysilane, methacryloxypropyltristrimethylsiloxysilane, (trimethylsilylethyldimethylsiloxy) silane, methacryloxypropyltris acryloxypropyltris (trimethylsilylethyldimethylsiloxy) silane, acryloxypropyltris ((tristrimethylsiloxysilyl) ethyldimethylsiloxy) silane, and methacryloxypropyltris ((tristrimethylsiloxysilyl) ethyldimethylsiloxy) silane. These may be used alone or in combinations of two or more.

The branched organopolysiloxane of the present invention has a viscosity of 1 to 500 mPa·s, 1 to 200 mPa·s, and most preferably 1 to 100 mPa·s at 25° C. The viscosity of a branched organopolysiloxane can be adjusted by changing n in formula (2) and the structure of R, Y, and Z.

The branched organopolysiloxane can be one type or a mixture of two or more types. If two or more organopolysiloxanes are used as a mixture, the viscosity of the mixture at 25° C. is preferably the viscosity described above.

The branched organopolysiloxanes of the present invention also have 4 to 16 silicon atoms per molecule.

In the present invention, component (B) is a branched organopolysiloxane that does not contain an alkoxy group in the molecule. Therefore, when a high energy ray-curable composition containing this component is prepared, it has excellent storage stability and can ensure good coating and curing properties over a long period of time.

### [Component (A)/(B) Mixing Ratio]

The mixing ratio of component (A) and component (B) is 5 to 95% by mass of component (A) and 95 to 5% by mass of component (B) relative to 100% by mass of the total amount of component (A) and component (B). When the ratio of components (A) and (B) is within this range, the viscosity of the curable composition is appropriate, good high energy ray curing properties are maintained, and the mechanical properties of the resulting cured material, especially the elastic modulus, can be designed to the desired value. By increasing the ratio of component (A), it is easy to design a cured material with high hardness and high elastic modulus. Meanwhile, a cured material with a low dielectric constant can easily be designed by increasing the ratio of component (B). The preferred ratio of component (A) depends on its structure and the number of (meth)acryloxy groups per molecule, but is between 15 and 85 mass percent, more preferably between 20 and 80 mass percent, and even more preferably between 25 and 75 mass percent of the total amount of components (A) and (B).

In addition to the above components (A) and (B), a component (B) that is a linear organopolysiloxane having one or more (meth)acryloxy groups in the molecule can be added to the high energy ray-curable composition of the present invention if desired. By adding this component, it may be easier to adjust the viscosity of the curable composition, high energy ray curability, hardness and elastic modulus of the resulting cured material. Examples of linear organopolysiloxanes having one or more (meth)acryloxy groups in the molecule include one-ended acryloxy-functional polydimethylsiloxane, one-ended methacryloxy-functional polydimethylsiloxane, one-ended acryloxy-functional polydimethyldiphenylsiloxane copolymer, one-ended methacryloxy-functional polydimethyldiphenylsiloxane copolymer, capped acryloxy-functional polydimethylsiloxane, capped methacryloxy-functional polydimethylsiloxane, capped acryloxy-functional polydimethyldiphenylsiloxane copolymer, capped methacryloxy-functional polydimethyldiphenylsiloxane copolymer, capped trimethylsilyl-functional polydimethyl (acryloxyalkylmethyl) siloxane copolymer, capped trimethylsilyl-functional polydimethyl(methacryloxyalkylmethyl) siloxane copolymer, capped acryloxy-functional polydimethyl(acryloxylalkylmethyl) siloxane copolymer, and capped methacryloxy-functional polydimethyl(methacryloxyalkylmethy) siloxane copolymer.

The amount of linear organopolysiloxane having one or more (meth)acryloxy groups per molecule serving as component (b) added to the composition of the present invention is not restricted, as long as the technical effect of the invention is not impaired, but it can be used in an amount of 0 to 10% by mass, preferably 0 to 5% by mass, of the total mass of the composition of the invention.

### [Organic Solvent-Free]

The high energy ray-curable compositions of the present invention are substantially free of organic solvents, as each of the aforementioned components can be used to achieve a viscosity suitable for coating agents without the substantial use of organic solvents. In the present specification, the phrase “substantially free of an organic solvent” means that the amount of organic solvent is less than 0.1 mass % of the total composition, preferably less than the analytical limit of analytical methods such as gas chromatography or the like. In the present invention, the desired viscosity can be achieved without the use of an organic solvent by adjusting the molecular structure and molecular weight of component (A) and component (B).

In addition to components (A) and (B) above, a photopolymerization initiator can be added to the high energy ray-curable composition of the present invention if desired. A photo-radical polymerization initiator can be used as the photoinitiator. The photoradical polymerization initiator generates free radicals by irradiating ultraviolet light or electron beams, which trigger a radical polymerization reaction, to cure the composition of the present invention. When the composition of the present invention is cured by electron beam irradiation, a polymerization initiator is normally not required.

The photo-radical polymerization initiators are known to be broadly classified into photo-fragmentation and hydrogen abstraction types. However, the photo-radical polymerization initiator used in the composition of the present invention can be selected arbitrarily from those known in the technical field, and is not limited to any particular one. Some photo-radical polymerization initiators can promote the curing reaction not only by irradiation with high energy rays such as ultraviolet light, but also by exposure to light in the visible light region.

Examples of specific photo-radical polymerization initiators include α-ketol compounds such as 4-(2-hydroxyethoxy)phenyl(2-hydroxy-2-propyl) ketone, α-hydroxy-α,α′-dimethylacetophenone, 2-methyl-2-hydroxypropiophenone, and 1-hydroxycyclohexylphenylketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, anisoin methyl ether; ketal compounds such as benzyl dimethyl ketal; aromatic sulfonyl chloride compounds such as 2-naphthalene sulfonyl chloride; photoactive oxime compounds such as 1-phenone-1,1-propanedione-2-(o-ethoxycarbonyl) oxime; benzophenone compounds such as benzophenone, benzoylbenzoic acid, and 3,3′-dimethyl-4-methoxybenzophenone; thioxansone compounds such as thioxansone, 2-chlorothioxansone, 2-methylthioxansone, 2,4-dimethylthioxansone, isopropylthioxansone, 2,4-dichlorothioxansone, 2,4-diethylthioxansone, and 2,4-diisopropylthioxansone; camphorquinone; and halogenated ketones.

Similarly, photoradical polymerization initiators suitable for use in the present invention include such bis-acylphosphine oxides as bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propylphenylphosphine oxide, bis-(2,4,6-trimethylbenzoyl)-phenylphosphine oxide, bis-(2,6-dimethoxybenzoyl)-2,4,4-trimethylpentylphosphine oxide, bis-(2,6-dichlorobenzoyl)-4-propylphenylphosphine oxide, bis-(2,6-dichlorobenzoyl)-2,5-dimethylphenylphosphine oxide, bis-(2,6-dimethoxybenzoyl)-2,5-dimethylphenylphosphine oxide, and bis-(2,4,6-trimethylbenzoyl)-phenylphosphine oxide; monoacylphosphine oxides such as 2,6-dimethoxybenzoyl diphenylphosphine oxide, 2,6-dichlorobenzoyldiphenylphosphine oxide, 2,4,6-trimethylbenzoylphenylphosphinic acid methyl ester, 2-methylbenzoyldiphenyl phosphine oxide, pivaloylphenylphosphinic acid isopropyl ester, and 2,4,6-trimethylbenzoyldiphenylphosphine oxide; anthraquinones such as anthraquinone, chloroanthraquinone, 2-methylanthraquinone, 2-ethylanthraquinone, 2-tert-butylanthraquinone, 1-chloroanthraquinone, 2-amylanthraquinone, and 2-aminoanthraquinone; benzoates such as ethyl 4-dimethylaminobenzoate, 2-(dimethylamino)ethyl benzoate, and p-dimethylbenzoic acid ethyl ester; titanocenes such as bis(η5-2,4-cyclopentadien-1-yl)-bis(2,6-difluoro-3-(1H-pyrrol-1-yl)phenyl) titanium, and bis(cyclopentadienyl)-bis[2,6-difluoro-3-(2-(1-pyr-1-yl)ethyl)phenyl]titanium; as well as phenyl disulfide 2-nitrofluorene, butyroin, anisoin ethyl ether, azobisisobutyronitrile, and tetramethylthiuram disulfide.

Examples of commercially available acetophenone-based photopolymerization initiators suitable for the present invention include Omnirad 907, 369, 369E, and 379 manufactured by IGM Resins. Examples of commercially available acylphosphine oxide-based photopolymerization initiators include Omnirad TPO, TPO-L, and 819 manufactured by IGM Resins. Examples of commercially available oxime ester-based photopolymerization initiators include Irgacure OXE01, OXE02, OXE03, and OXE04 manufactured by BASF Japan Ltd., N-1919, Adeka Arkls NCI-831, and NCI-831E manufactured by Adeka Corporation, and TR-PBG-304 manufactured by Changzhou Tronly New Electronic Materials Co., Ltd.

While the amount of the photoradical polymerization initiator added to the composition of the present invention is not particularly limited as long as the intended photoradical polymerization reaction or photocuring reaction occurs, it is generally used at an amount from 0.01 to 5 mass %, preferably from 0.05 to 3 mass %, relative to the total mass of the composition of the present invention.

Moreover, a photosensitizer may be used in combination with the aforementioned photoradical polymerization initiator. Use of a sensitizer can increase the photon efficiency of the polymerization reaction, and is particularly effective when the coating thickness of the composition is relatively thick or when a relatively long-wavelength LED light source is used, because use of longer wavelength light for the polymerization reaction compared to only using a photoinitiator is feasible. While not limited thereto, exemplary known sensitizers include anthracene-based compounds, phenothiazine-based compounds, perylene-based compounds, cyanine-based compounds, melocyanine-based compounds, coumarin-based compounds, benzylidene ketone-based compounds, and (thio) xanthene- or (thio) xanthone-based compounds such as isopropylthioxanthone, 2,4-diethylthioxanthone, alkyl-substituted anthracenes, squarylium-based compounds, (thia) pyrylium-based compounds, porphyrin-based compounds, and the like, with any photosensitizer capable of being used in the curable composition according to the present invention.

The cured product obtained from the curable composition of the present invention will have the desired properties of the cured product and the curing speed of the curable composition depending on the molecular chain length, molecular structure, and number of (meth)acryloxy groups per molecule in component (A) and component (B), and the viscosity of the cured composition can be designed to achieve the desired value. Furthermore, the cured product obtained by curing the curable composition of the present invention is also included in the scope of the present invention. Furthermore, the shape of the cured product obtained from the composition of the present invention is not particularly limited, and it may be a thin film coating layer, may be a sheet-like molded product or the like, may be injected into a specific site in an uncured state and then cured to form a filling material, or may be used as a sealing material for a laminated body, display device, or the like or as an intermediate layer. The cured product obtained from the composition of the present invention is preferably in the form of an injection molded protective adhesive layer and a thin film coating layer, and particularly preferably is a thin film insulating coating layer.

The curable composition of the present invention is suitably used as a coating agent or potting agent, particularly as an insulating coating agent or potting agent for an electronic device or electrical device.

The cured product obtained by curing the curable composition of the present invention is characterized by high mechanical properties, especially elastic modulus of elasticity, and a low dielectric constant. When the dielectric constant at room temperature and 100 KHz is measured by the capacitance method, it usually has a value of 3.0 or less. By optimizing the curable composition, the dielectric constant of the cured material can be reduced to 2.6 or less, making it useful as an insulating layer material for flexible displays.

If the curable composition of the present invention is used as an injection molding material and a coating agent, the viscosity of the entire composition is 500 mPa's or less at 25° C., as measured using an E-type viscometer, in order for the composition to have suitable flowability and workability for application to the substrate. When used as an injection molding material, the viscosity is preferably 200 mPa·s or less, especially 80 mPa's or less, but this depends on the gap into which it is to be injected. On the other hand, when used as a coating agent, the preferred viscosity range is 5 to 60 mPa·s, more preferably 5 to 30 mPa·s, and especially 5 to 20 mPa·s, considering application by the inkjet printing method, which is rapidly becoming more practical. The viscosity of the entire curable composition can be adjusted to the desired viscosity by using compounds with a preferred viscosity as each component so that the viscosity of the entire composition has the desired viscosity.

### [Component (C)]

When the high energy ray-curable composition of the present invention is applied to a surface of a substrate as a coating agent using any method, in order to improve the wettability of the composition on the substrate and form a defect-free coating film, component (C) selected from the following can be further added to the composition of the present invention containing the aforementioned components. The use of inkjet printing is particularly preferred as a method for coating the composition of the present invention on a substrate. Therefore, component (C) is a component that improves the wettability of the high energy ray-curable composition of the present invention on a substrate, and in particular significantly improves inkjet printing properties. Component (C) is at least one type of compound selected from a group consisting of the following (C1), (C2), and (C3).

### (i) Component (C1)

Component (C1) is a nonionic surfactant that does not contain a silicon atom and is not acrylic, in other words, a nonacrylic nonionic surfactant. “Nonacrylic” means that the surfactant does not have a (meth)acrylate group in a molecule thereof. Examples of surfactants that can be used as component (C1) include glycerol fatty acid esters, sorbitan fatty acid esters, polyoxyethylene alkyl ethers, polyoxyethylene alkyl phenyl ethers, alkyl glycosides, acetylene glycol polyether, and other organic nonionic surfactants, fluorine-based nonionic surfactants, and the like, and one or a combination of two or more types thereof can be used. Specific examples of component (C1) include the EMULGEN Series and RHEODOL series manufactured by Kao Corporation, SURFYNOL 400 series manufactured by Evonik Industries AG, and OLFINE E series manufactured by Nissin Chemical Co., Ltd. as organic nonionic surfactants, and FC-4400 series manufactured by 3M and MEGAFACE 550 and 560 series manufactured by DIC Corporation as fluorine-based nonionic surfactants.

Of these, SURFYNOL 400 series and OLFINE E series, which are alkynol polyethers, are particularly preferred.

(ii) Component (C2) is a nonionic surfactant containing a silicon atom and having an HLB value of 4 or less. Herein, the HLB value is a value that expresses the degree of affinity of a surfactant to water and organic compounds, and herein, a value defined by the Griffin method (20× sum of the formula weight of the hydrophilic portion/molecular weight) is used as the HLB value. Silicone polyether having a polyether as a hydrophilic portion, glycerol silicone having a (di)glycerol derivative as a hydrophilic portion, carbinol silicones having a hydroxyethoxy group as a hydrophilic portion, and the like are known silicon-containing nonionic surfactants. Of these surfactants, those with an HLB value of 4 or less, in other words, those with a hydrophilic portion mass fraction of 20 mass % or less, are preferably used in the composition of the present invention. Of these, carbinol silicone is particularly preferred.

(iii) Component (C3) is a silicone oil having a viscosity of 100 mPa·s or less at 25° C. Examples of silicone oils include capped trimethylsilyl-polydimethylsiloxane, capped dimethylvinylsilyl-polydimethylsiloxane, capped trimethylsilyl-dimethylsiloxy/methylvinylsiloxy copolymers, capped dimethylvinylsilyl-dimethylsiloxy/methylvinylsiloxy copolymers, capped trimethylsilyl-dimethylsiloxy/methylphenylsiloxy copolymers, capped trimethylsilyl-copolymers, capped dimethylvinylsilyl-dimethylsiloxy/diphenylsiloxy dimethylsiloxy/methylphenylsiloxy copolymers, capped dimethylvinylsilyl-dimethylsiloxy/diphenylsiloxy copolymers, and the like. Capped trimethylsilyl-polydimethylsiloxane and capped dimethylvinylsilyl-polydimethylsiloxane can be preferably used. A preferred viscosity range for the silicone oil is 2 to 100 mPa·s. A more preferred range is 5 to 100 mPa·s, and an even more preferred viscosity range is 5 to 50 mPa·s. Note that viscosity values herein were measured at 25° C. using a rotational viscometer described in the Examples.

Components (C1) through (C3) described above can be one or a combination of two or more thereof. The amount of component (C) in the curable composition is not particularly limited, but the total of components (C1) to (C3) (collectively referred to as component (C)) is preferably 0.05 mass % or more and 1 mass % or less relative to the total amount of 100 mass % of component (A) and component (B) described above. This is because if the amount of component (C) is less than 0.05 mass % relative to a total amount of 100 mass % of components (A) and (B), an effect of improving the wettability of the curable composition to a substrate may not be sufficient, and if the amount of component (C) exceeds 1 mass % relative to total amount of 100 mass % of components (A) and (B), there is a risk that component (C) may bleed out from a cured product after curing.

As component (C), a silicone oil of component (C3) is preferably used alone, or component (C3) is preferably used in combination with one or more components selected from a group consisting of component (C1) and component (C2). Component (C3) is preferably used alone as component (C).

### <Other Additives>

In addition to the aforementioned components, an additional additive may be added to the composition of the present invention if desired. Examples of additives include, but are not limited to, those described below.

### [Adhesion Imparting Agent]

An adhesion promoter can be added to the composition of the present invention to improve adhesion and close-fitting properties to a substrate in contact with the composition. When the curable composition of the present invention is used for applications such as coating agents, sealing materials, and the like that require adhesion or close-fitting properties to a substrate, an adhesion imparting agent is preferably added to the curable composition of the present invention. An arbitrary known adhesion promoter can be used, so long as the adhesion promoter does not interfere with a curing reaction of the composition of the present invention.

Examples of such adhesion promoters that can be used in the present invention include: organosilanes having a trialkoxysiloxy group (such as a trimethoxysiloxy group or a triethoxysiloxy group) or a trialkoxysilylalkyl group (such as a trimethoxysilylethyl group or triethoxysilylethyl groups) and a hydrosilyl group or an alkenyl group (such as a vinyl group or an allyl group), or organosiloxane oligomers having a linear structure, branched structure, or cyclic structure with approximately 4 to 20 silicon atoms; organosilanes having a trialkoxysiloxy group or a trialkoxysilylalkyl group and a methacryloxyalkyl group (such as a 3-methacryloxypropyl group), or organosiloxane oligomers having a linear structure, branched structure, or cyclic structure with approximately 4 to 20 silicon atoms; organosilanes having a trialkoxysiloxy group or a trialkoxysilylalkyl group and an epoxy group-bonded alkyl group (such as a 3-glycidoxypropyl group, a 4-glycidoxybutyl group, a 2-(3,4-epoxycyclohexyl)ethyl group, or a 3-(3,4-epoxycyclohexyl) propyl group), or organosiloxane oligomers having a linear structure, branched structure, or cyclic structure with approximately 4 to 20 silicon atoms; organic compounds having two or more trialkoxysilyl groups (such as trimethylsilyl groups or triethoxysilyl groups); reaction products of aminoalkyltrialkoxysilane and epoxy group-bonded alkyltrialkoxysilane, and epoxide group-containing ethyl polysilicate. Specific examples thereof include vinyl trimethoxysilane, allyl trimethoxysilane, allyl triethoxysilane, hydrogen triethoxysilane, 3-glycidoxypropyl trimethoxysilane, 3-glycidoxypropyl triethoxysilane, 2-(3,4-epoxycyclohexyl)ethyl trimethoxysilane, 3-methacryloxypropyl trimethoxysilane, 3-methacryloxypropyl triethoxysilane, 1,6-bis(trimethoxysilyl) hexane, 1,6-bis(triethoxysilyl) hexane, 1,3-bis[2-(trimethoxysilyl)ethyl]-1,1,3,3-tetramethyldisiloxane, reaction products of 3-glycidoxypropyl triethoxysilane and 3-aminopropyl triethoxysilane, condensation reaction products of a methylvinyl siloxane oligomer blocked with a silanol group and a 3-glycidoxypropyl trimethoxysilane, condensation reaction products of a methylvinyl siloxane oligomer blocked with a silanol group and a 3-methacryloxypropyl triethoxysilane, and tris(3-trimethoxysilylpropyl) isocyanurate.

The amount of the adhesion promoter to be added to the curable composition of the present invention is not particularly limited. However, since it does not promote curing properties of the curable composition or discoloration of a cured product, the amount is preferably within a range of 0.01 to 5 parts by mass, or within a range of 0.01 to 2 parts by mass, relative to a total of 100 parts by mass of components (A) and (B).

### [Additional Optional Additives]

Another additive may be added to the composition of the present invention in addition to or in place of the adhesion imparting agent described above, if desired. Examples of additives that can be used include leveling agents, silane coupling agents not included in those listed above as adhesion imparting agents, UV absorbers, antioxidants, polymerization inhibitors, fillers (reinforcing fillers, insulating fillers, thermal conductive fillers, and other functional fillers), and the like. If necessary, an appropriate additive can be added to the composition of the present invention. Furthermore, a thixotropy imparting agent may also be added to the composition of the present invention if necessary, particularly when used as a potting agent or sealing agent.

### [Application]

The high energy ray-curable organopolysiloxane composition of the present invention can be cured not only by ultraviolet light but also by electron beams, which is another aspect of the present invention.

By irradiating the composition of the present invention with high energy rays such as ultraviolet light, a radical polymerization reaction proceeds to form a cured product.

Examples of high energy rays include UV light, gamma rays, X-rays, alpha rays, electron beams, and the like. In particular, examples include ultraviolet light, X-rays, and electron beams irradiated from a commercially available electron beam irradiating device. Of these, ultraviolet light is preferable from the perspective of efficiency of catalyst activation, and ultraviolet light within a wavelength range of 280 to 405 nm is preferable from the perspective of industrial use. Furthermore, the irradiation dose varies depending on the type of high energy ray-activated catalyst used, but in the case of ultraviolet light, the integrated irradiation dose at a wavelength of 365 nm is preferably within a range of 100 mJ/cm² to 10 J/cm².

The curable composition of the present invention has low viscosity, and is particularly useful as a material for forming an insulating layer for various articles, particularly electronic and electrical devices. The composition of the present invention can be applied on a substrate or sandwiched between two substrates, at least one of which includes a material that allows ultraviolet light or electron beams to pass, and the composition can be cured by irradiating ultraviolet light or electron beams to form an insulating layer. In this case, the composition of the present invention can be patterned when applied to a substrate, and then the composition can be cured. Alternatively, the composition can be applied to a substrate, and cured and uncured portions can be left during curing by ultraviolet light or electron beam irradiation. Thereafter, an uncured portion can be removed with a solvent to form an insulating layer having a desired pattern. In particular, when the cured layer of the present invention is an insulating layer, the layer can be designed to have a low dielectric constant of less than 3.0.

The curable composition of the present invention provides favorable transparency of the cured product obtained therefrom, and is particularly suitable as a material for forming an insulating layer for touch panels, displays and other display devices. In this case, an arbitrary desired pattern may be formed as described above if necessary on the insulating layer. Therefore, a display device such as touch panel, display, or other display device containing an insulating layer obtained by curing the high energy ray-curable organopolysiloxane composition of the present invention is also an aspect of the present invention.

Furthermore, the curable composition can also be used to form an insulating coating layer (insulating film) by curing after coating an article. Therefore, the composition of the present invention can be used as an insulating coating agent. Furthermore, a cured product formed by curing the curable composition of the present invention can be used as an insulating coating layer.

An insulating film formed from the curable composition of the present invention can be used for various applications. In particular, use is possible as a component of an electronic device or as a material used in a process of manufacturing the electronic device. Electronic devices include semiconductor devices, magnetic recording heads, and other electronic apparatuses. For example, the curable composition of the present invention can be used in an insulating film of a semiconductor device, such as an LSI, system LSI, DRAM, SDRAM, RDRAM, D-RDRAM, or a multi-chip module multilayer circuit board, an interlayer insulating film for a semiconductor, an etch stopper film, a surface protection film, a buffer coat film, a passivation film in LSI, a cover coat for a flexible copper cladding plate, a solder resistant film, and a surface protection film for an optical device.

Furthermore, the high energy ray-curable composition of the present invention can be used as a coating agent, or as a potting agent, and particularly as an insulating potting agent for electronic devices and electrical devices.

The composition of the present invention can be used as a material for forming a coating layer on a surface of a substrate, particularly using an inkjet printing method. In this case, the composition of the present invention particularly preferably contains component (C) described above.

The present invention is further described below based on Examples, but the present invention is not limited to the Examples below.

### EXAMPLES

The high energy ray-curable composition of the present invention and a cured product thereof of the present invention will be described below in further detail using examples. Measurements and evaluations in the examples and comparative examples were conducted as follows.

### [Viscosity of Curable Composition]

The viscosity (mPa·s) of the composition at 25° C. was measured using a rotary viscometer (E type viscometer VISCONIC EMD produced by TOKIMEC CORPORATION).

### [Appearance of Curable Composition and Cured Product Obtained Therefrom]

The appearance of the curable composition and the 0.1 mm thick cured material obtained therefrom was evaluated by visual observation.

### [Preparation of Curable Composition]

Each material at the amounts listed in Table 1 below was placed in a brown plastic container and mixed well, using a planetary mixer to prepare the curable composition.

### [Wettability of Curable Composition on Substrate (Contact Angle of Composition)]

Two microliters of the curable composition was dripped onto a silicon nitride coated glass substrate, and the contact angle (units: °) of the curable composition immediately after dripping and 15 seconds after dripping was measured at 23° C. using a contact angle measuring device DM-700 manufactured by Kyowa Interface Science Co., Ltd.

### [Curing of Curable Composition and Preparation of Dynamic Viscoelastic Test Piece]

Approximately 0.55 g of curable composition was injected between two glass substrates with a 1.0 mm thick spacer interposed therebetween. The composition was cured by irradiating LED light of 405 nm wavelength at an energy level of 2 J/cm² through a glass substrate from the outside to prepare a 10×50×1.0 (thickness) mm³ strip-like test piece.

### [Viscoelasticity Measurement of Organopolysiloxane Cured Material]

A strip-like test piece prepared from the cured organopolysiloxane was subjected to a viscoelasticity measurement in a temperature range from −40° C. to 160° C. using an MCR—302 dynamic viscoelasticity measuring instrument manufactured by Anton Paar under conditions of a frequency of 1 Hz, strain of 0.1%, stress of −0.1 N/mm², and a temperature increase rate 3° C./min., and the value of the storage modulus (unit: Pa) at 130° C. was recorded.

### [Curing of Curable Composition and Preparation of Sample for Dielectric Constant Measurement]

A mold having a thickness of 1 mm having circular holes with an inner diameter of 40 mm was placed on a PET film coated with a fluoropolymer release agent, and approximately 1.3 g of the curable composition was poured into a hole thereof. A PET film similar to that described above was placed over the composition, and a 10 mm thick glass plate was placed thereon. By irradiating an LED light having a wavelength of 405 nm at an energy amount of 2 J/cm² from above, the composition was cured to prepare a disk-shaped organopolysiloxane cured product having a diameter of 40 mm and a thickness of 1 mm.

### [Dielectric Constant of Organopolysiloxane Cured Product]

A tin foil having a diameter of 33 mm and a thickness of 0.007 mm was pressed onto both surfaces of the prepared organopolysiloxane cured product. In order to improve close-fitting properties between the cured product and the foil, a small amount of silicone oil, if necessary, was used for pressing. The capacitance at room temperature and 100 KHz was measured by an E4990A precision impedance analyzer manufactured by Keysight Technologies to which a parallel plate electrode having a diameter of 30 mm was connected. The dielectric constant was calculated using measured capacitance values, separately measured thicknesses of the cured product, and electrode area values.

### [Examples and Comparative Examples]

High energy ray-curable compositions were prepared with the compositions (parts by mass) shown in Table 1 using each of the following components.
(A1) Isobornyl acrylate (monofunctional)
(A2) Tricyclodecane dimethanol diacrylate (bifunctional)
(A3) Tricyclodecane dimethanol dimethacrylate (bifunctional)
(A4) Trimethylolpropane triacrylate (trifunctional)
(A5) Tentaerythritol tetraacrylate (tetrafunctional)
(B1) Methacryloxypropyl trimethylsiloxysilane
(B2) Methacryloxypropyl tris(tris-trimethylsiloxysilyl)ethyldimethylsiloxy) silane (b′) Polydimethylsiloxane blocked at both ends with an acryloxyoctyldimethylsiloxy group (average number of silicon atoms: 17)
(C) Polydimethylsiloxane blocked at both ends with a trimethylsiloxy group (product name: DOWSIL™ SH 200 Fluid (viscosity at 25° C.: 20 mPa·s), manufactured by Dow Silicones Corporation)
(D) 2,4,6-Trimethylbenzoyl diphenylphosphine oxide (product name: Omnirad TPO, manufactured by IGM Resins)
(E) Dibutylhydroxytoluene (polymerization inhibitor)

TABLE 1

| | Example | Example | Example | Example | Example | Example | Example | Example | Example | Comparative | Comparative |
|---|---|---|---|---|---|---|---|---|---|---|---|
| Component | 1 | 2 | 3 | 4 | 5 | 6 | 7 | 8 | 9 | Example 1 | Example 2 |
| (A1) | 59.7 | 21.0 | 21.0 | 51.4 | 51.4 | 49.8 | 47.4 | 20.8 | 20.8 | 29.7 | 59.7 |
| (A2) | | 49.0 | | | | | | | | | |
| (A3) | | | 49.0 | | | | | | | | |
| (A4) | | | | | | | 22.6 | 49.2 | 49.2 | 69.5 | |
| (A5) | | | | 8.6 | 8.6 | 20.2 | | | | | |
| (B1) | | 29.2 | 29.2 | 39.2 | | 29.2 | 28.2 | 29.2 | 29.2 | | |
| (B2) | 39.5 | | | | 39.2 | | | | | | |
| (b′) | | | | | | | | | | | 39.5 |
| (C) | | | | | | | | | 0.3 | | |
| (D) | 0.5 | 0.5 | 0.5 | 0.5 | 0.5 | 0.5 | 0.5 | 0.5 | 0.5 | 0.5 | 0.5 |
| (E) | 0.3 | 0.3 | 0.3 | 0.3 | 0.3 | 0.3 | 0.3 | 0.3 | 0.3 | 0.3 | 0.3 |
| Total | 100.0 | 100.0 | 100.0 | 100.0 | 100.0 | 100.0 | 100.0 | 100.0 | 100.3 | 100.0 | 100.0 |
| Appearance of | Clear | Clear | Clear | Clear | Clear | Clear | Clear | Clear | Clear | Clear | Clear |
| curable | | | | | | | | | | | |
| composition | | | | | | | | | | | |
| Viscosity of | 13 | 19 | 17 | 7 | 18 | 11 | 9 | 18 | 18 | 39 | 15 |
| composition | | | | | | | | | | | |
| Appearance of | Clear | Clear | Clear | Clear | Clear | Clear | Clear | Clear | Clear | Clear | Translucent |
| cured product | | | | | | | | | | | |
| Storage Elastic | 1 × 10⁵ | 2 × 10⁷ | 7 × 10⁷ | 1 × 10⁸ | 1 × 10⁸ | 1 × 10⁷ | 1 × 10⁷ | 1 × 10⁸ | 1 × 10⁸ | 1 × 10⁸ | 1 × 10⁸ |
| Modulus | | | | | | | | | | | |
| of Cured Product | | | | | | | | | | | |
| Dielectric constant | 2.5 | 2.6 | 2.6 | 2.5 | 2.5 | 2.7 | 2.6 | 3.0 | 3.0 | 3.4 | 2.6 |
| of cured product | | | | | | | | | | | |

The contact angles of the composition in Example 8 immediately after dropping and 15 seconds after dropping were 15° and 4°, respectively. Meanwhile, the contact angles of the composition in Example 9 immediately after dropping and 15 seconds after dropping were 15° and 3°, respectively.

As shown in Table 1, the high energy ray-curable compositions of the present invention (Examples 1-9) have suitable viscosities and high transparency for application to substrates as injection molding materials and as coating agents, especially by inkjet printing. Furthermore, the compositions have favorable wettability to the substrate, and the addition of component (C) can further improve wettability (Example 9). In addition, cured products obtained from the compositions of the present invention exhibit low dielectric properties. In addition, by increasing the crosslinking density of the compositions, the resulting cured products have a high elastic modulus at high temperatures and excellent heat resistance. Meanwhile, the composition containing no component (B) (Comparative Example 1) does not exhibit low dielectric properties, and the composition containing a linear double-ended acryloxy-modified polysiloxane as component (b′) instead of component (B) (Comparative Example 2) does not exhibit good transparency.

### INDUSTRIAL APPLICABILITY

The high energy ray-curable composition of the present invention is suitable for the applications described above, and especially as a material for forming an insulating layer for touch panels and display devices such as displays, in particular flexible displays.

1. A high energy ray-curable composition comprising:
(A) 5 parts by mass to 95 parts by mass of a compound having one or more (meth)acryloxy groups and no silicon atoms in the molecule; and
(B) 95 parts by mass to 5 parts by mass of a branched organopolysiloxane having one (meth)acryloxy group and no alkoxy group in the molecule, some of the oxygen atoms being substitutable with a divalent alkylene group having no more than 6 carbon atoms;
wherein the composition contains substantially no organic solvent, and the viscosity of the entire composition measured at 25° C. using an E-type viscometer is 500 mPa's or less.

2. The high energy ray-curable composition according to claim 1, wherein component (A) is a compound having one (meth)acryloxy group and no silicon atom or a mixture of two or more compounds having one (meth)acryloxy group and no silicon atom.

3. The high energy ray-curable composition according to claim 1, wherein component (A) is a mixture of one or more compounds having one (meth)acryloxy group and no silicon atom and one or more compounds having two or more (meth)acryloxy groups and no silicon atom.

4. The high energy ray-curable composition according to claim 1, wherein component (A) contains a compound having one or more acryloxy groups and no silicon atoms in the molecule.

5. The high energy ray-curable composition according to claim 1, wherein component (B) is a branched organopolysiloxane having an organosiloxy unit represented by the following general formula (1) and having no alkoxy group, some of the oxygen atoms being substitutable with a divalent alkylene group having no more than 6 carbon atoms:
RSiO_{3/2} (1)
where R is a group containing a (meth)acryloxy group.

6. The high energy ray-curable composition according to claim 1, wherein component (B) is a branched organopolysiloxane represented by the following general formula (2):
RSi[O(SiZ₂X),SiY₃]₃ (2)
where R is a group containing a (meth)acryloxy group, X is a divalent alkylene group having no more than 6 carbon atoms, Y is a group selected from an unsubstituted or fluorine-substituted monovalent hydrocarbon group having no more than 10 carbon atoms, or OSiZ₃, where Z is an unsubstituted or fluorine-substituted monovalent hydrocarbon group having no more than 10 carbon atoms, and n is 0 or 1.

7. The high energy ray-curable composition according to claim 1, wherein the viscosity of the entire composition measured at 25° C. using an E-type viscometer is 5 to 100 mPa·s.

8. The high energy ray-curable composition according to claim 1, wherein the viscosity of the entire composition measured at 25° C. using an E-type viscometer is 5 to 30 mPa·s.

9. An insulating coating agent comprising the high energy ray-curable composition according to claim 1.

10. A cured product of the high energy ray-curable composition according to claim 1.

11. A method of using an insulating coating layer of a cured product of the high energy ray-curable composition according to claim 8.

12. A display device comprising a layer containing a cured product of the high energy ray-curable composition according to claim 1.
